(19) United States
(12) Patent Application Publication
(10) Pub. No.: US 2008/0130697 A1
(43) Pub. Date: Jun. 5, 2008

(54) SEMICONDUCTOR LASER

(75) Inventors: Motoharu MIYASHITA, Tokyo (JP); Akihiro SHIMA, Tokyo (JP); Masayoshi TAKEMI, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/743,700

(22) Filed: May 3, 2007

(30) Foreign Application Priority Data
Nov. 30, 2006 (JP) 2006-324170

(51) Int. Cl. H01S 5/22

(52) U.S. Cl. 372/45.01

(57) ABSTRACT

A semiconductor laser having a ridge structure, comprises a lower cladding layer, an active layer, and an upper cladding layer that are sequentially arranged and supported by a GaAs semiconductor substrate having a misorientation angle of 7 degrees or more. The active layer is AlGaAs. The upper and lower cladding layers are AlGaAsP and the composition ratio of P in the upper and lower cladding layers is higher than 0 and no more than 0.04.

### FIELD OF THE INVENTION

The present invention relates to a semiconductor laser used in optical disc systems, and more particularly to a semiconductor laser having a ridge structure formed on a misoriented GaAs substrate having a misorientation angle of 7 degrees or more.

### BACKGROUND ART

FIG. 4 is a cross-sectional view of a conventional 780 nm semiconductor laser having a ridge structure. In this 780 nm semiconductor laser, a lower cladding layer 31 of Al_{0.5}Ga_{0.5}As, an active layer 32 of Al_{0.1}Ga_{0.9}As, and an upper cladding layer 33 of Al_{0.5}Ga_{0.5}As are sequentially formed over a GaAs substrate 11 having a misorientation angle of 7 degrees or more. Further, a GaAs contact layer 15 is formed on a portion of the upper cladding layer 33, and the other portions of the upper cladding layer 33 are covered with an insulating film 16. Further, a top electrode 17 is formed over the GaAs contact layer 15, and a bottom electrode 18 is formed on the lower surface of the GaAs substrate 11. Thus, in this 780 nm semiconductor laser, the upper and lower cladding layers 33 and 31, which sandwich the active layer 32 of Al_{0.1}Ga_{0.9}As therebetween, are formed of Al_{0.5}Ga_{0.5}As and hence differ in lattice constant from the active layer 32 by approximately 600 ppm.

FIG. 5 is a cross-sectional view of a conventional two-wavelength semiconductor laser. This two-wavelength semiconductor laser includes a 780 nm semiconductor laser such as that shown in FIG. 4 and a 650 nm semiconductor laser which are formed on a GaAs substrate 11 having a misorientation angle of 7 degrees or more. In the 650 nm semiconductor laser, a lower cladding layer 19 of Al_{0.35}Ga_{0.15}In_{0.5}P, an active layer 20 of Ga_{0.5}In_{0.5}P, and an upper cladding layer 21 of Al_{0.35}Ga_{0.15}In_{0.5}P are sequentially formed over the GaAs substrate 11. Further, a GaAs contact layer 22 is formed on a portion of the upper cladding layer 21, and the other portions of the upper cladding layer 21 are covered with an insulating film 16. Further, a top electrode 23 is formed over the GaAs contact layer 22. Thus, in this 650 nm semiconductor laser, the upper and lower cladding layers 21 and 19, which sandwich the active layer 20 of Ga_{0.5}In_{0.5}P therebetween, are formed of Al_{0.35}Ga_{0.15}In_{0.5}P and have substantially the same lattice constant as the active layer 20.

As described above, in conventional 780 semiconductor lasers, the active layer and the upper and lower cladding layers (which sandwich the active layer therebetween) differ in lattice constant by approximately 600 ppm, which causes stress to the active layer. Semiconductor lasers having a ridge structure are especially susceptible to this stress, since an insulating film and an electrode are formed near the emission point of the active layer. It should be noted that this stress is asymmetrically applied since the semiconductor laser device is formed on a GaAs substrate having a misorientation angle of 7 degrees or more. This causes the polarization angle to deviate from 0 degrees, resulting in a reduced polarization ratio.

Further, the asymmetry of such stress applied to the active layer of the 780 nm semiconductor laser is more significant in the case of a two-wavelength laser, since the ridge portion of each laser is not located at the center portion of the substrate.

It should be noted that Japanese Laid-Open Patent Publication No. 2004-349286 discloses a 780 nm semiconductor laser in which an active layer containing As but not containing P and upper and lower cladding layers containing P are formed over a GaAs substrate having a misorientation angle of 10 degrees such that the active layer and the upper and lower cladding layers have substantially the same lattice constant. Further, Japanese Laid-Open Patent Publication No. 2001-185810 discloses a 780 nm semiconductor laser in which an active layer of AlGaAs (or AlGaInAs) and upper and lower cladding layers of AlGaAsP (or AlGaAs) are formed over a GaAs substrate having a misorientation angle of 10 degrees or more. Further, Japanese Patent Publication No. 60-220983 discloses a technique of forming an active layer and upper and lower cladding layers such that they have the same lattice constant. However, the semiconductor lasers disclosed in the above patent publications are neither semiconductor lasers having a ridge structure nor two-wavelength lasers, and therefore do not have the structural problems described above.

### SUMMARY OF THE INVENTION

The present invention has been devised to solve these problems. It is, therefore, an object of the present invention to provide a semiconductor laser having a ridge structure that exhibits a polarization angle close to 0 degrees and hence a high polarization ratio even if it is formed on a misoriented GaAs substrate having a misorientation angle of 7 degrees or more.

According to one aspect of the present invention, a semiconductor laser having a ridge structure, comprises: a lower cladding layer, an active layer, and an upper cladding layer that are sequentially formed over a GaAs semiconductor substrate having a misorientation angle of 7 degrees or more. The active layer is formed of AlGaAs. The upper and lower cladding layers are formed of AlGaAsP and the composition rate of P in the upper and lower cladding layers is higher than 0 and equal to or lower than 0.04.

Thus, the present invention can provide a semiconductor laser having a ridge structure that exhibits a polarization angle close to 0 degrees and hence a high polarization ratio even if it is formed on a misoriented GaAs substrate having a misorientation angle of 7 degrees or more.

Other and further objects, features and advantages of the invention will appear more fully from the following description.

### BRIEF DESCRIPTION OF THE DRAWINGS

FIG. 1 is a cross-sectional view of a 780 nm semiconductor laser having a ridge structure according to a first embodiment of the present invention.

FIG. 2 is a cross-sectional view of a multibeam semiconductor laser according to a third embodiment of the present invention.

FIG. 3 is a cross-sectional view of a two-wavelength semiconductor laser according to a fourth embodiment of the present invention.

FIG. 4 is a cross-sectional view of a conventional 780 nm semiconductor laser having a ridge structure.

FIG. 5 is a cross-sectional view of a conventional two-wavelength semiconductor laser.

### DETAILED DESCRIPTION OF THE PREFERRED EMBODIMENTS

### First Embodiment

FIG. 1 is a cross-sectional view of a 780 nm semiconductor laser having a ridge structure according to a first embodiment of the present invention. In this semiconductor laser, a lower cladding layer 12 of Al_{0.5}Ga_{0.5}As_{0.98}PO_{0.02}, an active layer 13 of Al_{0.1}Ga_{0.9}As, and an upper cladding layer 14 of Al_{0.5}Ga_{0.5}As_{0.98}PO_{0.02} are sequentially formed over a GaAs substrate 11 having a misorientation angle of 7 degrees or more (e.g., 10 degrees). Further, a GaAs contact layer 15 is formed on a portion of the upper cladding layer 14, and the other portions of the upper cladding layer 14 are covered with an insulating film 16. Further, a top electrode 17 is formed over the GaAs contact layer 15, and a bottom electrode 18 is formed on the lower surface of the GaAs substrate 11.

It should be noted that this semiconductor laser has a ridge structure formed by removing both sides of the upper portion of the upper cladding layer 14 by etching so as to form a ridge portion, as shown in FIG. 1. As a result, the portions of the upper cladding layer 14 on both sides of the ridge portion have a reduced thickness; that is, their upper surfaces are located near the active layer 13. Since the insulating film 16 and top electrode 17 are formed over the upper cladding layer 14 having such a configuration (as described above), the active layer 13 tends to suffer stress.

However, according to the present embodiment, the active layer 13 is formed of AlGaAs, and the upper and lower cladding layers 14 and 12 are formed of AlGaAsP and the composition rate of P in these cladding layers is higher than 0 (and equal to or lower than 0.04), which allows for a reduction in the difference in lattice constant between the active layer 13 and the upper and lower cladding layers 14 and 12 and hence a reduction in the distortion of the crystalline structure, as described below. The lattice constant of an AlGaAs layer increases with increasing composition rate of Al. (GaAs has a smaller lattice constant than AlGaAs.) Since adding P to an AlGaAs layer results in a reduction in its lattice constant, the difference in lattice constant between an AlGaAs active layer containing a low composition rate of Al and an AlGaAs cladding layer containing a high composition rate of Al can be reduced by adding an appropriate amount of P to the cladding layer. That is, according to the present embodiment, the compositions of the active layer 13 and the upper and lower cladding layers 14 and 12 are such that these layers have substantially the same lattice constant. Therefore, the active layer 13 suffers only reduced stress, allowing the semiconductor laser (having a ridge structure) to exhibit a polarization angle close to 0 degrees and hence a high polarization ratio even if the semiconductor laser is formed on a GaAs substrate having a misorientation angle of 7 degrees or more. Further, the composition rate of P in the cladding layers is adjusted to 0.04 or less, as described above, to prevent crystal defects caused by increased stress to the active layer.

### Second Embodiment

In a semiconductor laser having a ridge structure according to a second embodiment of the present invention, a lower cladding layer 12 of Al_{0.5}Ga_{0.5}As, an active layer 13 of Al_{0.1}Ga_{0.89}In_{0.01}As, and an upper cladding layer 14 of Al_{0.5}Ga_{0.5}As are sequentially formed over a GaAs substrate 11 having a misorientation angle of 7 degrees or more (e.g., 10 degrees). All other components are similar to those described in connection with the first embodiment.

According to the present embodiment, the upper and lower cladding layers 14 and 12 are formed of AlGaAs, and the active layer 13 is formed of AlGaInAs and the composition rate of In in the active layer 13 is higher than 0 (and equal to or lower than 0.02), which allows for a reduction in the difference in lattice constant between the active layer 13 and the upper and lower cladding layers 14 and 12 and hence a reduction in the distortion of the crystalline structure, as described below. The lattice constant of an AlGaAs layer slightly increases with increasing composition rate of Al. (GaAs has a smaller lattice constant than AlGaAs.) Since adding In to an AlGaAs layer containing a low composition rate of Al results in an increase in its lattice constant, the difference in lattice constant between an AlGaAs active layer containing a low composition rate of Al and an AlGaAs cladding layer containing a high composition rate of Al can be reduced by adding an appropriate amount of In to the active layer. That is, according to the present embodiment, the compositions of the active layer 13 and the upper and lower cladding layers 14 and 12 are such that these layers have substantially the same lattice constant. Therefore, the active layer 13 suffers only reduced stress, allowing the semiconductor laser (having a ridge structure) to exhibit a polarization angle close to 0 degrees and hence a high polarization ratio even if the semiconductor laser is formed on a GaAs substrate having a misorientation angle of 7 degrees or more. Further, the composition rate of In in the active layer is adjusted to 0.02 or less, as described above, to prevent crystal defects caused by increased stress to the active layer.

### Third Embodiment

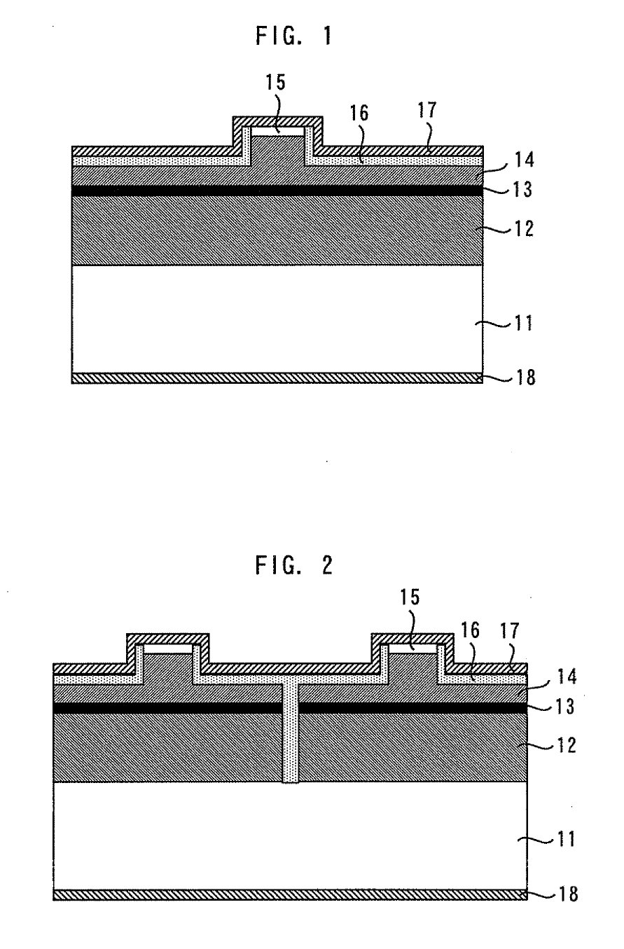

FIG. 2 is a cross-sectional view of a multibeam semiconductor laser according to a third embodiment of the present invention. This multibeam semiconductor laser includes a semiconductor laser such as that of the first or second embodiment and another semiconductor laser. They are formed on the same substrate and have the same emission wavelength (780 nm). That is, this 780 nm multibeam semiconductor laser has two or more emission points. This multibeam semiconductor laser can also achieve the effects described in connection with the first or second embodiment.

### Fourth Embodiment

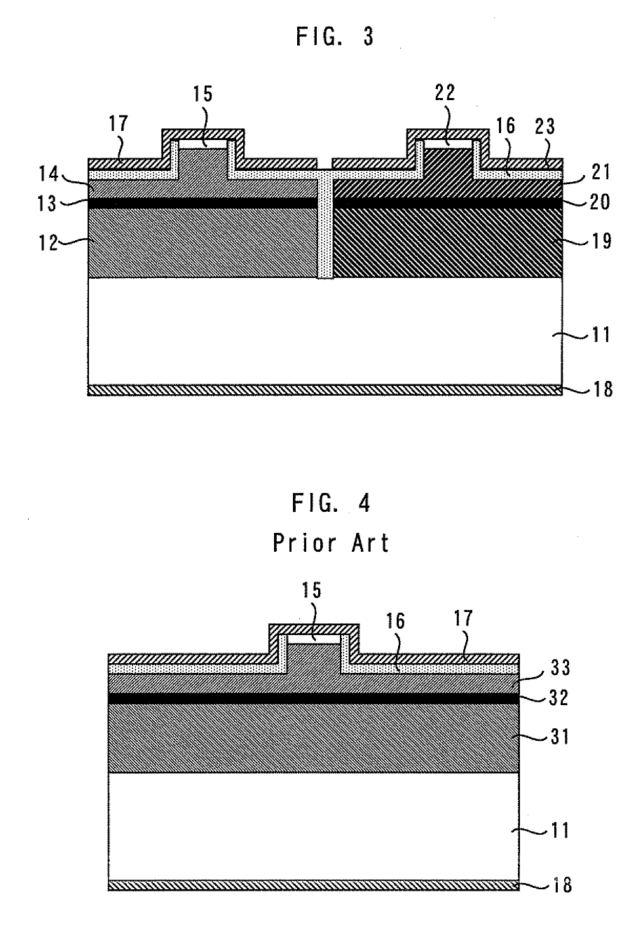

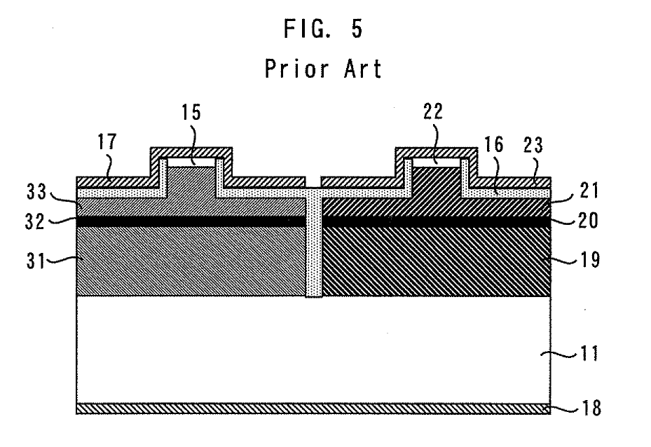

FIG. 3 is a cross-sectional view of a two-wavelength semiconductor laser according to a fourth embodiment of the present invention. This two-wavelength semiconductor laser includes a semiconductor laser such as that of the first or second embodiment and another semiconductor laser. They are formed on the same substrate but have different emission wavelengths. More specifically, in this two-wavelength semiconductor laser, a 780 nm semiconductor laser such as that of the first or second embodiment and a 650 nm semiconductor laser are formed on a GaAs substrate 11.

In the 650 nm semiconductor laser, a lower cladding layer 19 of Al_{0.35}Ga_{0.15}In_{0.5}P, an active layer 20 of Ga_{0.5}In_{0.5}P, and an upper cladding layer 21 of Al_{0.35}Ga_{0.15}In_{0.5}P are sequentially formed over the GaAs substrate 11. Further, a GaAs contact layer 22 is formed on a portion of the upper cladding layer 21, and the other portions of the upper cladding layer 21 are covered with an insulating film 16. Further, a top electrode 23 is formed over the GaAs contact layer 22.

According to the present embodiment, in the 780 nm semiconductor laser, the compositions of the active layer 13 and the upper and lower cladding layers 14 and 12 are adjusted such that these layers have substantially the same lattice constant, as in the first and second embodiments. Therefore, this two-wavelength semiconductor laser can also achieve the effects described in connection with the first or second embodiment.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2006-324170, filed on Nov. 30, 2006 including specification, claims, drawings and summary, on which the Convention priority of the present application is based, are incorporated herein by reference in its entirety.

1. A semiconductor laser having a ridge structure, comprising a lower cladding layer, an active layer, and an upper cladding layer that are sequentially arranged and supported by a GaAs substrate having a misorientation angle of at least 7 degrees, wherein
said active layer is AlGaAs, and
said upper and lower cladding layers are AlGaAsP and composition ratio of P in said upper and lower cladding layers is higher than 0 and no more than 0.04.

2. A semiconductor laser having a ridge structure, comprising a lower cladding layer, an active layer, and an upper cladding layer that are sequentially arranged and supported by a GaAs substrate having a misorientation angle of at least 7 degrees, wherein
said active layer is AlGaInAs and composition ratio of In in said active layer is higher than 0 and no more than 0.02, and
said upper and lower cladding layers are AlGaAs.

3. A semiconductor laser structure comprising a first semiconductor laser according to claim 1 and a second semiconductor laser, said first and second semiconductor lasers being disposed on a common substrate, said first and second semiconductor lasers having the same emission wavelength or different emission wavelengths.

4. A semiconductor laser structure comprising a first semiconductor laser according to claim 2 and a second semiconductor laser, said first and second semiconductor lasers being disposed on a common substrate, said first and second semiconductor lasers having the same emission wavelength or different emission wavelengths.
